(19) United States
(12) Patent Application Publication
(10) Pub. No.: US 2020/0099014 A1
(43) Pub. Date: Mar. 26, 2020

(54) METHOD OF PRODUCING ELECTRONIC COMPONENT SUBSTRATE, METHOD OF PRODUCING DISPLAY PANEL, ELECTRONIC COMPONENT SUBSTRATE, AND DISPLAY PANEL

(71) Applicant: Sharp Kabushiki Kaisha, Sakai City (JP)

(72) Inventors: Atsushi HACHIYA, Sakai City (JP); Hiroaki FURUKAWA, Sakai City (JP)

(21) Appl. No.: 16/562,487

(22) Filed: Sep. 6, 2019

Related U.S. Application Data
(60) Provisional application No. 62/733,745, filed on Sep. 20, 2018.

(51) Int. Cl. H01L 51/56; H01L 51/52; H01L 51/00; G02F 1/1339; G02F 1/1337

(52) U.S. Cl. CPC H01L 51/56; H01L 51/5237; H01L 51/0017; G02F 2001/133792; H01L 51/5231; G02F 1/1339; G02F 1/13378; H01L 51/5215

(57) ABSTRACT

A method of producing an element substrate includes (A) a process of forming a transparent electrode film containing a transparent metal oxide on an upper side of an insulating film located above a conductive film, (B) a process of forming a photoresist film on an upper side of the transparent electrode film and patterning the photoresist film, (C) a process of removing a portion of the transparent electrode film not covered by the photoresist film to form an opening H extending through the transparent electrode film, and (D) a process of removing a portion of the insulating film not covered by the photoresist film and the transparent electrode film to form a contact hole extending to the conductive film. The element substrate produced by the method includes an electrode including the transparent electrode film electrically connected to the conductive film at the contact hole.

### CROSS REFERENCE TO RELATED APPLICATION

This application claims priority from U.S. provisional patent application No. 62/733,745 filed on Sep. 20, 2018. The entire contents of the priority application are incorporated herein by reference.

### TECHNICAL FIELD

The technology disclosed herein relates to a method of producing an element substrate, a method of producing a display panel, an element substrate, and a display panel.

### BACKGROUND

A known display panel used as a main component of a display device includes two substrates facing each other and an electro-optical material, such as liquid crystals, sealed between the substrates. One of the substrates is an element substrate (TFT substrate, thin film transistor substrate) and includes thin film transistors (TFTs) having a conductive film, such as a semiconductor film and a metal film, as switching elements. Pixel electrodes formed of an electrode film is disposed above the TFTs with an insulating film therebetween. This configuration allows an electrical signal from an external device to be transmitted to the electro-optical material at a predetermined timing, and thus a display panel displays an image viewable from the side of the outer surface of a counter substrate, which is the other of the substrates. Here, the TFTs and the pixel electrodes are electrically connected to each other through contact holes in the films, such as the insulating film, located between them. Phenomena, such as alignment disorder of the liquid crystals, reflection, and diffraction, are likely to occur at portions of the element substrate near the contact holes, which have a different three-dimensional structure from the other portions. The polarization direction of the light passing through the portions around the contact holes is shifted by the above-described phenomena, resulting in the light leakage to the image display surface of the display panel and color wash-out. This decreases the contrast. To prevent this, a light-blocking layer that blocks light is generally disposed on the counter substrate to cover the contact holes and the portions around the contact holes.

In recent years, there is a need for a super-high-resolution display panel used, for example, in a head mounted display (HMD, head-worn display). To obtain a super-high-resolution display panel, the installation area of the light-blocking film needs to be reduced such that the aperture ratio of the display screen decreases and the light transmittance improves. Furthermore, it is important to increase the screen contrast by suppressing the above-described decrease in contrast caused by light leakage. It is difficult to achieve both the high transmission and high contrast. However, both the characteristics are exhibited by making the diameter of the contact hole smaller. It is better for the contact hole, which connects the pixel electrode in the upper layer of the element substrate with the TFT in the lower layer of the element substrate, to have a smaller diameter, for example, in view of the alignment accuracy during formation of the layers.

There is a process limitation in the reduction in diameter of the contact hole, which is typically formed by photolithography and dry etching. In particular, a resist film having a typical resist pattern formed by photolithography is thinner at a portion around the opening. During dry etching, the resist is also etched and the opening in the resist pattern is widened. Thus, the diameter of the opening in the resist pattern increases as the dry etching progresses. The contact hole formed by using the resist pattern having the increased opening diameter has a larger diameter than the opening in the original resist pattern formed by photolithography. In particular, the contact hole that connects the pixel electrode, which is included in the upper layer of the element substrate to control the alignment of the liquid crystals, with the conductive film in the TFT, which is included in the lower layer of the element substrate, is likely to have an increased diameter, because the contact hole is deep.

For example, Japanese Patent No. 4999799 listed below discloses a method of producing a semiconductor device. In the method, a metal film etched using a pattern formed by photolithography is used as a mask, and contact holes are formed by etching in a silicon film and a resin film, which are located below the metal film.

In the method described in Japanese Patent No. 4999799, the metal film needs to be removed at the end. If the metal film is removed by etching, a portion of the TFT exposed to the inner surface of the contact hole for connection would be damaged. For example, Japanese Patent No. 4999799 describes a method in which an etching mask is formed by using titanium and then the etching mask is removed by dry etching after formation of contact holes. However, this method does not allow commonly used metal films, such as a film formed of titanium, a titanium-aluminum multi-layer film, and a titanium-aluminum-titanium multi-layer film, to be used as the conductive film constituting the TFT. Furthermore, dry etching is highly likely to leave unremoved portions, for example, due to the presence of foreign substances on the surface, compared with wet etching. The unremoved portions of the metal film used as the etching mask may cause a defect such as current leakage between the pixel electrodes.

### SUMMARY

The present technology was made in view of the above-described circumstances and an object thereof is to provide an element substrate having small-diameter contact holes formed with high accuracy. Another object of the present technology is to provide a display panel in which light leakage at portions around the contact holes is reduced. A still another object of the present technology is to provide a simple method of producing the above-described element substrate and a simple method of producing the above-described display panel.

(1) An embodiment of the technology disclosed herein is a method of producing an element substrate including a conductive film, an insulating film located above the conductive film, and an electrode located above the insulating film and including a transparent electrode film electrically connected to the conductive film. The method includes (A) a transparent electrode film formation process of forming the transparent electrode film containing a transparent metal oxide on an upper side of the insulating film, (B) a photoresist formation process of forming a photoresist film on an upper side of the transparent electrode film and patterning the photoresist film, (C) a transparent electrode film opening formation process of selectively removing a portion of the transparent electrode film not covered by the patterned photoresist film to form an opening extending through the transparent electrode film, and (D) a contact hole formation process of selectively removing, by etching, a portion of the insulating film not covered by the patterned photoresist film and the transparent electrode film having the opening to form a contact hole extending to the conductive film through the transparent electrode film and the insulating film.

(2) Furthermore, an embodiment of the technology disclosed herein is a method of producing an element substrate in which, in addition to the above-described configuration (1), the electrode is formed of the transparent electrode film located above the insulating film and formed in a predetermined pattern. The method further includes (E) a contact metal film formation process of forming a contact metal film having light-blocking properties on an upper surface of the transparent electrode film having the contact hole to cover the entire inner surface of the contact hole and to electrically connect a portion of the transparent electrode film around the opening with a portion of the conductive film exposed to the inside of the contact hole, and (F) an electrode formation process of removing a portion of the contact metal film and a portion of the transparent electrode film to shape the contact metal film and the transparent electrode film into the shape of the electrode.

(3) Furthermore, an embodiment of the technology disclosed herein is a method of producing an element substrate in which, in addition to the above-described configuration (2), in the electrode formation process, the portion of the contact metal film and the portion of the transparent electrode film are removed at the same time by wet etching.

(4) Furthermore, an embodiment of the technology disclosed herein is a method of producing an element substrate further including, in addition to the above-described configuration (2) or (3), (G) a contact formation process of removing all the contact metal film having the shape of the electrode except a portion forming the inner surface of the contact hole and a portion connected to the transparent electrode film.

(5) Furthermore, an embodiment of the technology disclosed herein is a method of producing a display panel including the process of producing an element substrate according to any one of the above-described configurations (1) to (4).

(6) Furthermore, an embodiment of the technology disclosed herein is an element substrate including a conductive film, an insulating film located above the conductive film, and an electrode located above the insulating film and including a transparent electrode film electrically connected to the conductive film. The insulating film has a contact hole extending to the conductive film through the insulating film. A contact metal film having light-blocking properties covers the entire inner surface of the contact hole and electrically connects the transparent electrode film with a portion of the conductive film exposed to the inside of the contact hole.

(7) Furthermore, an embodiment of the technology disclosed herein is an element substrate in which, in addition to the above-described configuration (6), the contact metal film is not disposed over at least a portion of the electrode, and the electrode is a transparent electrode through which light passes.

(8) Furthermore, an embodiment of the technology disclosed herein is an element substrate in which, in addition to the above-described configuration (6), the contact metal film is disposed over the electrode, and the electrode is a non-transparent electrode having light-blocking properties.

(9) Furthermore, an embodiment of the technology disclosed herein is a display panel including the element substrate according to any one of the above-described configurations (6) to (8).

(10) Furthermore, an embodiment of the technology disclosed herein is a display panel in which, in addition to the above-described configuration (9), the display panel is a liquid crystal panel.

(11) Furthermore, an embodiment of the technology disclosed herein is a display panel in which, in addition to the above-described configuration (9), the display panel is an organic EL panel.

According to the present technology, a high-resolution display panel is obtained by a simple method.

### BRIEF DESCRIPTION OF THE DRAWINGS

FIG. 1 is a schematic cross-sectional view illustrating a display area of a transmission-type liquid crystal panel according to a first embodiment.

FIG. 2 is a plan view schematically illustrating pixels in a display area of an element substrate.

FIG. 3 is a schematic cross-sectional view illustrating the element substrate including a TFT.

FIG. 4 is a schematic plan view illustrating a connection between the TFT and the pixel electrode.

FIG. 5 is a cross-sectional view taken along line A-A in FIG. 4.

FIG. 6A is an explanatory view illustrating a step in a method of producing an element substrate.

FIG. 6B is an explanatory view illustrating a step in a method of producing the element substrate.

FIG. 6C is an explanatory view illustrating a step in a method of producing the element substrate.

FIG. 6D is an explanatory view illustrating a step in a method of producing the element substrate.

FIG. 7A is an explanatory view illustrating a step in a method of producing an element substrate.

FIG. 7B is an explanatory view illustrating a step in a method of producing the element substrate.

FIG. 7C is an explanatory view illustrating a step in a method of producing the element substrate.

FIG. 7D is an explanatory view illustrating a step in a method of producing the element substrate.

FIG. 7E is an explanatory view illustrating a step in a method of producing the element substrate.

FIG. 8A is an explanatory view schematically illustrating light leakage near a contact hole in a conventional liquid crystal panel.

FIG. 8B is an explanatory view schematically illustrating light leakage near a contact hole in a liquid crystal panel according to a first embodiment.

FIG. 9A is an explanatory view illustrating a step in a method of producing an element substrate according to a modification of the first embodiment.

FIG. 9B is an explanatory view illustrating a step in the method of producing the element substrate.

FIG. 9C is an explanatory view illustrating a step in the method of producing the element substrate.

FIG. 9D is an explanatory view illustrating a step in the method of producing the element substrate.

FIG. 9E is an explanatory view illustrating a step in the method of producing the element substrate.

FIG. 10 is a schematic plan view illustrating connection between a TFT and a pixel electrode in a transmission-type liquid crystal panel according to a second embodiment.

FIG. 11 is a cross-sectional view taken along line B-B in FIG. 10.

FIG. 12 is a magnified cross-sectional view schematically illustrating a portion near a contact hole of an element substrate in a top-emitting organic EL panel according to a third embodiment.

### DETAILED DESCRIPTION

### First Embodiment

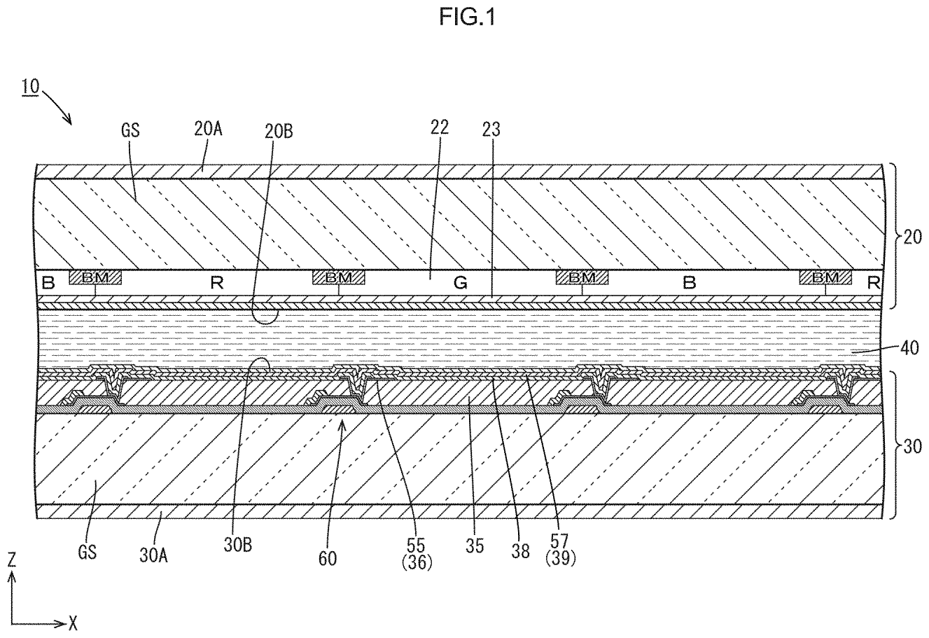

A first embodiment is described with reference to FIGS. 1 to 8B. In the first embodiment, a liquid crystal panel (one example of a display panel) 10 is described as an example. The X axis, the Y axis, and the Z axis are indicated in some of the drawings, and each of the axes indicates the same direction in the respective drawings. In the following description, the dimension along the X axis of a component or an area may be referred to as an X dimension, and the dimension along the Y axis may be referred to as an Y dimension. Furthermore, the upper side in FIG. 1 is a front side or a front surface side (the lower side in FIG. 1 is a rear side or a rear surface side). For the identical components, one of them is designated with a reference numeral and the reference numeral for the others is omitted in some cases. In the drawings, for ease of explanation, the components have simplified shapes in some cases and some of the components are on a different scale from the others.

The liquid crystal panel 10 according to the first embodiment is applicable as a display panel of a display device for a mobile terminal, such as a smart phone, and a wearable terminal, such as a head mounted display (HMD). The present technology is preferably applicable to a display panel required to have super high resolution. The screen size of the liquid crystal panel 10 is preferably in a range of about a few inches to about a dozen inches, which is categorized as a small size or a small to medium size in general, but the screen size is not limited thereto. For example, the technology is applicable to a display device having a screen size of tens of inches, which is categorized as a medium or large (very large) size.

In the first embodiment, a transmission-type liquid crystal panel 10 having a substantially oblong planar shape is described as an example. The liquid crystal panel 10 uses the front plate surface as a display surface and displays an image viewable from the front side of the liquid crystal panel 10. A backlight device (not illustrated), for example, is disposed on the rear surface side of the liquid crystal panel 10 such that light is applied from the rear surface side to the liquid crystal panel 10. The liquid crystal panel 10 is a “liquid crystal cell” having a known schematic configuration and includes two substantially oblong planar substrates 20 and 30 attached to each other with the plate surfaces thereof facing each other as illustrated in FIG. 1. The substrates 20 and 30 are attached to each other by a sealing material (not illustrated), such as an epoxy resin, with a space being kept between the substrates 20 and 30. The space is filled with a liquid crystal material whose alignment is changed by application of an electrical signal. The space filled with the liquid crystal material is a liquid crystal layer 40. The liquid crystal material may be one selected from known liquid crystal materials. For example, the liquid crystal material may be injected into the space between the substrates 20 and 30 by a “vacuum impregnation matehood” in which the liquid crystal material is injected under a reduced pressure into a space between the substrates 20 and 30 attached to each other or by a “one drop fill method” in which the liquid crystal material is drop added onto one of the substrates 20 and 30 and then the substrates 20 and 30 are attached to each other.

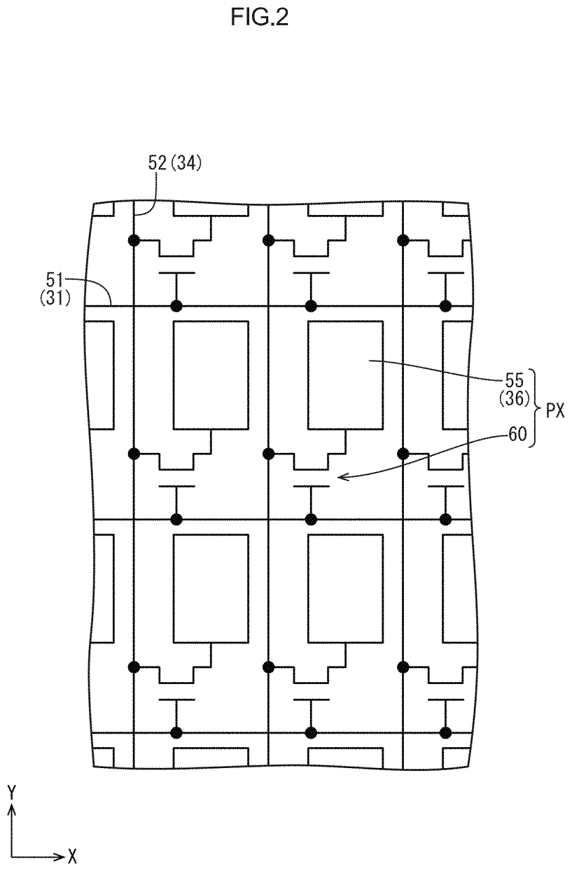

In in FIG. 1, one of the substrates 20 and 30 on the front side is a CF substrate (may be referred to as a color filter substrate or a counter substrate) 20 and the other on the rear side is an element substrate (may be referred to as a device substrate, an array substrate, a matrix substrate, or a thin filter transistor substrate (TFT substrate)) 30. The liquid crystal panel 10 has a display area (active area) capable of displaying an image in the middle of the plate surface. The display area has pixels PX (see FIG. 2), which will be described later. A frame-shaped area surrounding the display area and not having the pixels PX is a non-display area (non-active area) incapable of displaying an image. Although not illustrated and described in detail, the frame-shaped area as the non-display area has terminals. A transmission component that transmits electrical signals sent from an external signal source and a driving member that displays an image in the display area are connected to or mounted on the frame-shaped area. Furthermore, a reduction in the frame-shaped area is widely employed mainly in small to middle size liquid crystal panels. To achieve the smaller frame width, a display circuit, such as a gate driver, and a power circuit are formed in the frame-shaped area at the same time as the formation of the pixels PX such that the element substrate incorporates driving functions.

As illustrated in FIG. 1, the substrates 20 and 30 each include a substantially transparent glass substrate GS having insulating properties and through which visible light passes. Although the glass substrate GS is used in the first embodiment, a silicon substrate or a heat-resisting plastic substrate, for example, may be used instead of the glass substrate GS. The CF substrate 20 and the element substrate 30 may include light transmissive substrates formed of different materials. The substrates 20 and 30 have polarizing plates 20A and 30A on the outermost surfaces (surface away from the liquid crystal layer). For example, plates formed by stretching a transparent film impregnated with iodine or a dye in one direction may be used as the polarizing plates 20A and 30A. Various films having predetermined patterns are laminated on the inner surface (adjacent to the liquid crystal layer 40, facing the other substrate) of each of the glass substrates GS by a known film formation technique, such as photolithography, to form various components. The substrates 20 and 30 have alignment films 20B and 30B that determine the original alignment of the liquid crystal material in the liquid crystal layer 40 on the inner most surfaces or the surfaces in contact with the liquid crystal layer 40. For example, the alignment films 20B and 30B are polyimide alignment films. The substrates 20 and 30 are attached to each other after being subjected to necessary alignment treatments, such as rubbing and photoalignment, such that the surfaces having the alignment films face each other.

In the first embodiment, the liquid crystal panel that operates in an In-Plane Switching (IPS) mode is described as an example. The CF substrate 20 of the first embodiment does not have an electrode and, as illustrated in FIG. 1, includes a color filter 22 including coloring portions R, G, B that selectively transmits red (R), green (G), and blue (B) light on the inner side (adjacent to the liquid crystal layer 40) over a display area and an overcoat film 23 and an alignment film 20B on the upper side (inner side, adjacent to the liquid crystal layer 40) of the color filter 22. The color filter 22 includes a black matrix BM located at the borders between the coloring portions R, G, and B. The black matrix BM covers non-pixel portions (the formation areas of the TFTs 60 and the contact holes 50 in the display area) of the element substrate 30, which will be described later. The overcoat film 23 and the alignment film 20B are disposed in a solid pattern over the entire area.

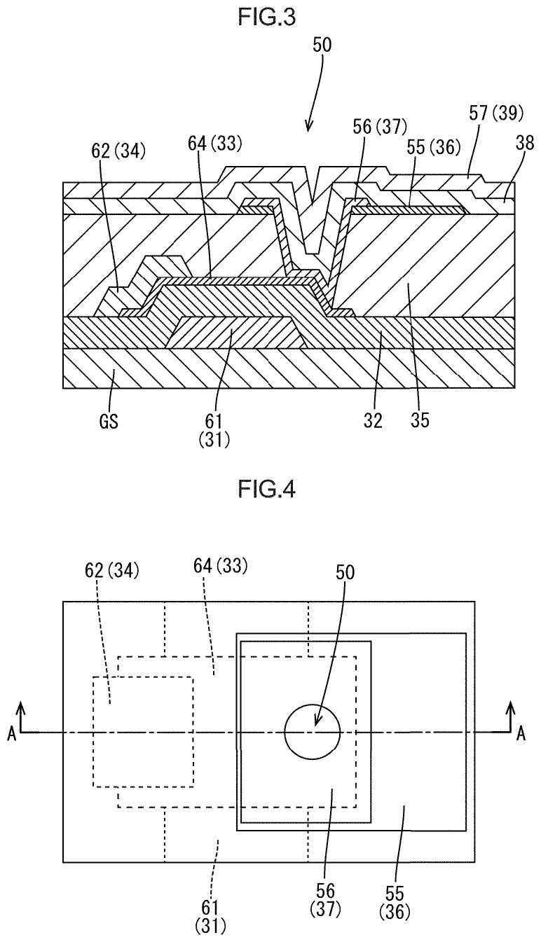

As illustrated in FIGS. 1 and 2, the element substrate 30 includes various components including TFTs (one example of an element) 60, pixel electrodes 55, and a common electrode 57, in the inner layer (adjacent to the liquid crystal layer 40). In FIGS. 1 and 2, the components are simplified, and some components are not illustrated. In the first embodiment, the element substrate 30 including an inverted staggered TFT 60 illustrated in FIG. 3 is described as an example. As illustrated in FIG. 3, for example, the inner layers of the element substrate 30 include, in this order from the lower side (adjacent to the glass substrate GS), a first metal film (gate metal film) 31, a gate insulating film 32, a semiconductor film (one example of a conductive film) 33, a second metal film (source metal film) 34, a passivation film (protective insulating film, one example of an insulating film) 35, a first transparent electrode film (one example of a transparent electrode film) 36, a contact metal film 37, an interlayer insulating film 38, and a second transparent electrode film 39. Although not illustrated in FIG. 3, the alignment film 30B in contact with the liquid crystal layer 40 is disposed in a solid pattern on the upper surface of the second transparent electrode 39 over the entire area as illustrated in FIG. 1.

Each of the first metal film 31 and the second metal film 34 of the above-described films is a single-layer film formed of one of metal materials selected from copper (Cu), titanium (Ti), aluminum (Al), molybdenum (Mo), and tungsten (W), for example, or a multi-layer film or an alloy formed of different kinds of the metal materials. The gate insulating film 32 and the interlayer insulating film 38 are each formed of silicon nitride (SiNₓ) or silicon oxide (SiO₂). The semiconductor film 33 is a silicon thin film formed of amorphous silicon or low-temperature poly-silicon or an oxide thin film including indium (In), gallium (Ga), and zinc (Zn), which are oxide semiconductors. The passivation film 35 may be an inorganic insulating film formed of silicon nitride or oxide silicon or an acrylic resin film (for example, Poly(methyl methacrylate) (PMMA)) and protects the TFTs 60 and the wiring lines below the passivation film 35. The first transparent electrode film 36 and the second transparent electrode film 39 are each formed of a transparent electrode material containing a transparent oxide metal, such as indium tin oxide (ITO), indium zinc oxide (IZO), and zinc oxide (ZnO). The contact metal film 37 may be formed of any conductive and light-blocking material. For example, the contact metal film 37 is a single-layer film formed of one of the metal materials selected from copper, titanium, aluminum, molybdenum, and tungsten or a multi-layer film or an alloy formed of different kinds of the metal materials, as the first and second metal films 31 and 34. The first metal film 31, the semiconductor film 33, the second metal film 34, the first transparent electrode film 36, the contact metal film 37, and the second transparent electrode film 39 are each formed in a predetermined pattern. The insulating films including the gate insulating film 32, the passivation film 35, and the interlayer insulating film 38 are each formed in a substantially solid pattern.

In the first embodiment, the passivation film 35 is a multi-layer film including a silicon nitride layer and a silicon oxide layer. The first transparent electrode film 36 is an IZO film containing IZO, which is a transparent metal oxide. Furthermore, the contact metal film 37 is a Mo film containing molybdenum.

The above-described films constitute the inner layers of the element substrate 30 in which the pixel electrodes 55 and the TFTs 60 as switching elements(display elements) are arranged in a matrix (rows and columns) along the row direction (X axis direction) and the column direction (Y axis direction) over the display area, as illustrated, for example, in FIG. 2. Gate lines (gate bus lines, row wiring lines, row control lines, scanning lines) 51 and source lines (source bus lines, column wiring lines, column control lines, data lines) 52 are arranged in a grid pattern to surround the TFTs 60 and the pixel electrodes 55. The gate lines 51 and the source lines 52 are respectively formed of the first metal film 31 and the second metal film 34. The gate insulating film 32 is located between the gate lines 51 and the source lines 52 at the intersections. Although not illustrated in FIG. 2, the first metal film 31 may form capacitor lines extending along the gate lines 51 across the pixel electrodes 55.

The pixel electrode 55 has a substantially oblong (rectangular) shape in plan view as illustrated, for example, in FIG. 2 and is formed of the first transparent electrode film 36 located above the second metal film 34 with the passivation film 35 having a relatively large thickness therebetween, as illustrated, for example, in FIG. 3. The common electrode 57 is formed of the second transparent electrode film 39 located above the first transparent electrode film 36 with the interlayer insulating film 38 therebetween. Although the common electrode 57 is not illustrated in plan view, the common electrode 57 is disposed over the multiple pixels and has openings, such as slits, in an area overlapping the first transparent electrode film 36. The shape, number, arrangement of the slits may be suitably determined. When a potential difference occurs between the pixel electrode 55 and the common electrode 57, capacitance is formed due to the presence of the interlayer insulating film 38 between the electrodes 55 and 57. Thus, an electric field is applied to a portion of the liquid crystal layer 40 near the element substrate 30. In the liquid crystal layer 40, the orientation of the liquid crystal molecules, which are aligned in substantially parallel to the plate surface of the element substrate 30 by the alignment films 20B and 30B during no application of voltage (initial state), is changed by the application of an electric field in accordance with the direction of the electric field. This changes the state of the light passing through the liquid crystal panel 10, and thus an image is displayed in the display area.

As illustrated, for example, in FIG. 3, the inverted staggered TFT 60 of the first embodiment includes a gate electrode 61 formed of the first metal film 31, a source electrode 62 formed of the second metal film 34, and a channel 64 formed of the semiconductor film 33. The TFT 60 does not include a drain electrode formed of the second metal film 34. In the TFT 60 having such a configuration, the space between the source lines 52 is smaller than that in a widely used TFT including a drain electrode by a space of the drain electrode, and thus the TFT 60 requires a smaller installation area. The TFT 60 having the above-described configuration is advantageous for the liquid crystal panel 10 to have higher resolution and higher transmission. In the TFT 60, as described later, the contact metal film 37 is disposed to connect the channel 64 formed of the semiconductor film 33 with the pixel electrode 55 formed of the first transparent electrode film 36, and thus the contact metal film 37 forms a contact 56 that functions as the drain electrode of the TFT 60. As illustrated in FIG. 3, in the TFT 60 according to the first embodiment, the channel 64 formed of the semiconductor film 33 is disposed above the gate electrode 61 formed of the first metal film 31 with the gate insulating film 32 therebetween, and the source electrode 62 formed of the second metal film 34 is disposed above the semiconductor film 33. The FTF 60, which is connected to the gate line 51 and the source line 52 (FIG. 2), is also connected to the pixel electrode 55 through the contact metal film 37 at the contact hole 50 in the passivation film 35.

As illustrated in FIG. 2, the pixel electrodes 55 and the TFTs 60, which are connected to the pixel electrodes 55, in the element substrate 30 constitute the pixels PX. The colors exhibited by the pixels PX correspond to the coloring portions R, G, and B of the color filter 22 opposed to the pixel electrodes 55. As described above, when a potential is applied to the pixel electrode 55 in response to an electrical signal sent from an external signal source connected to the frame-shaped area or the driving circuit located in the frame-shaped area to the gate line 51 and the source line 52, a potential difference occurs between the pixel electrode 55 and the common electrode 57. This forms capacitance due to the presence of the interlayer insulating film 38 between the pixel electrode 55 and the common electrode 57, applying an electrical field to a portion of the liquid crystal layer 40 near the element substrate 30. The electrical field changes the alignment state of the liquid crystal layer 40, and the change in the alignment state changes the polarization state of the transmitting light. Thus, the amount of light transmitting through the liquid crystal panel 10 is controlled for each of the pixels PX, and a predetermined color image is displayed in a display area.

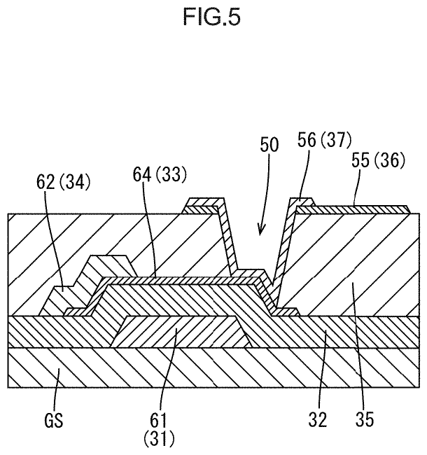

The element substrate 30 of the first embodiment is characterized by the connection structure between the TFT 60 and the pixel electrode 55 at the contact hole 50. Hereinafter, the connection structure is described with reference to FIGS. 4 and 5 schematically illustrating the connection structure. In FIGS. 4 and 5, the interlayer insulating film 38, the second transparent electrode film 39, the alignment film 30B, which are located above the contact metal film 37 forming the contact 56, are not illustrated for ease of visual understanding of the connection structure. In FIG. 4, the electrodes and the pixel electrode 55 of the TFT 60 are simplified. As illustrated in FIGS. 4 and 5, the contact hole 50 of the first embodiment extends through the first transparent electrode film 36 and the passivation film 35 to the semiconductor film 33 forming the channel 64 of the TFT 60. The contact 56 formed of the contact metal film 37 covers the entire inner surface of the contact hole 50 including the bottom surface formed of the exposed semiconductor film 33. The contact metal film 37, which overlaps the entire contact hole 50 in plan view, also overlaps a portion of the first transparent electrode film 36 around the opening and electrically connects the semiconductor film 33 with the first transparent electrode film 36. In the element substrate 30 of the first embodiment, the contact hole 50 and the portion around the contact hole 50 are shielded from light by being covered with the contact metal film 37. This reduces the possibility that the light emitted by the backlight device and passed through the glass substrate GS will be scattered or reflected by the three-dimensional structure, such as the contact hole 50, and spread as light leaked to the image display surface.

Next, a method of producing the element substrate 30 having the above-described configuration is described. The TFTs 60, the wiring line layer containing the gate lines 51 and the source lines 52, and the passivation film 35 (i.e., the layers below the first transparent electrode film 36) of the element substrate 30 are formed by any known method without any limitation. The following processes (a) to (h) are merely examples and the method of producing the element substrate 30 is not limited to the method including these processes.

(a) First, the first metal film 31 is formed on the glass substrate GS, for example, by sputtering. Then, for example, a photoresist film that has a pattern of the gate electrodes 61 and the gate lines 51 is formed on the first metal film 31, and portions of the first metal film 31 not covered by the resist are selectively removed by etching, and thus the gate electrodes 61 and the gate lines 51 are formed. The photoresist film is removed, for example, by plasma asking using oxygen or by a stripping process using a chemical.

(b) Next, the gate insulating film 32, the semiconductor film 33, and the second metal film 34 are formed, for example, by plasma CVD or sputtering, on the gate electrodes 61 and the gate lines 51. Then, a photoresist film including a thick first resist and a thin second resist is formed on the second metal film 34. The thick first resist is formed over a formation area of the active area of the TFTs 60, the source electrodes 62, and the source lines 52. The thin second resist is formed over a formation area of the channels 64 of the TFTs 60. The photoresist film is formed by multiple exposures, for example, using a half-tone mask or a gray-tone mask.

(c) Next, portions of the second metal film 34 and the semiconductor film 33 that are not covered by the resists of the photoresist film formed in the process (b) are removed by etching to form the active areas of the TFTs 60, the source electrodes 62, and the source lines 52. Then, the second resist is selectively removed from the photoresist film, for example, by asking for a duration of time that allows only the first resist to remain unremoved.

(d) Next, the photoresist film of the process (c) including only the first resist is used as a mask and portions of the second metal film 34 that are not covered by the first resist are removed by etching to form the channels 64 of the TFTs 60. Then, the remaining portions of the photoresist film are all removed. The formation processes of (b) to (d) are effective when the second metal film 34 is removed by wet etching. When dry etching in which etching selectivity between the second metal film 34 and the semiconductor film 33 is sufficiently high is employed, the photoresist may include only the first resist, eliminating the need of a special process such as multiple exposures.

(e) Next, the passivation film 35 is formed over the entire surface. The passivation film 35 is formed, for example, by plasma CVD. The passivation film 35 of the first embodiment is a multi-layer film including a silicon nitride layer and an oxide silicon layer as described above.

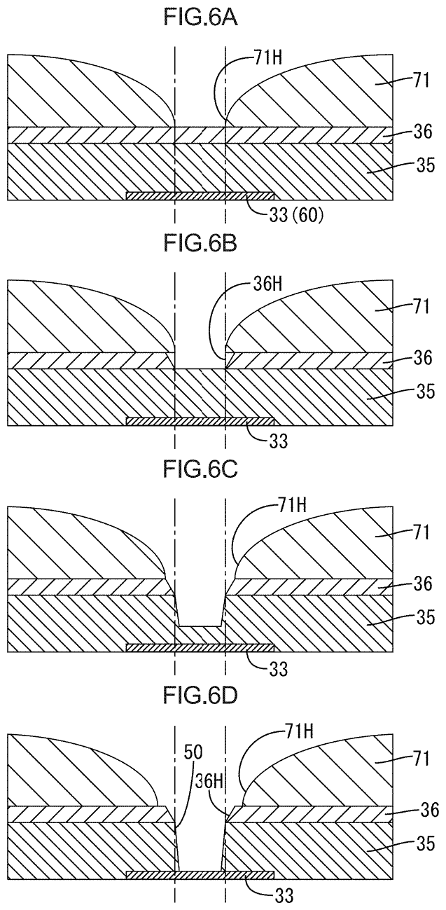

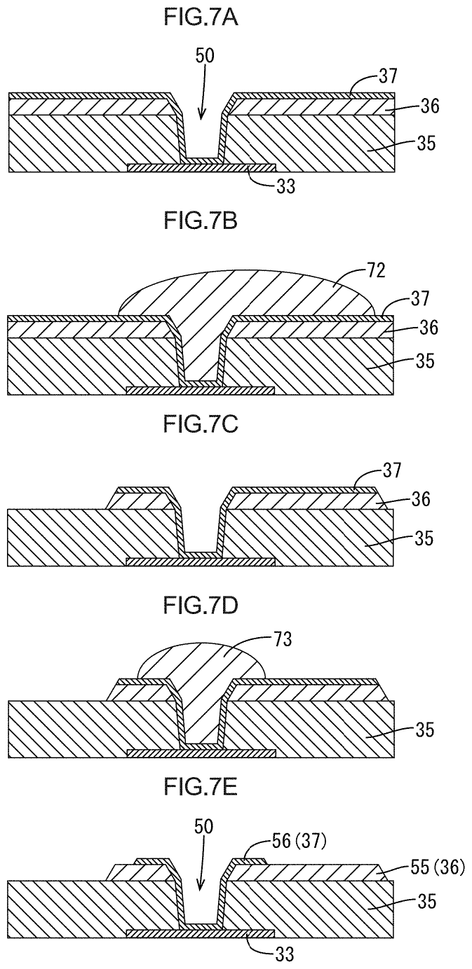

After the above-described formation of the passivation film 35, the contact hole 50 extending through the passivation film 35 and the pixel electrode 55 on the passivation film 35 is formed to obtain the connection structure connecting the pixel electrode 55 with the TFT 60. The method of producing the element substrate 30 of the first embodiment is characterized by the above-described processes. A production method including processes (A) to (G-2) is described as an example with reference to FIGS. 6A to 6D and FIGS. 7A to 7E. In FIGS. 6A to 6D and FIGS. 7A to 7E, only the semiconductor film 33 (one example of a conductive film) of the components of the TFT 60, which is connected to the pixel electrode 55, is schematically illustrated.

(A) First, a transparent metal oxide, such as ITO and IZO, is sputtered on the upper surface of the passivation film 35 formed in a solid pattern to form the first transparent electrode film 36 (transparent electrode film formation process). In the first embodiment, the first transparent electrode film 36 contains IZO as the transparent metal oxide as described above.

(B) Next, a photoresist is applied onto the first transparent electrode film 36 and developed after exposure to light using a photomask (not illustrated). Thus, as illustrated in FIG. 6A, a first photoresist film (photoresist film) 71 that has a pattern having an opening 71H at a formation position of the contact hole 50 is obtained (photoresist film formation process). Examples of the photoresist include TFR series (registered trademark) available from TOKYO OHKA KOGYO CO., LTD.

(C) Next, a portion of the first transparent electrode film 36 not covered by the first photoresist film 71 is selectively removed by dry etching or wet etching under conditions where the first transparent electrode film 36 is the removal target. Thus, as illustrated in FIG. 6B, an opening 36H extending through the first transparent electrode film 36 is formed (transparent electrode film opening formation process). In the first embodiment in which the first transparent electrode film 36 is an IZO film, the opening 36H having substantially the same size as the opening 71H in the first photoresist film 71 is formed by wet etching using a mixture of acids, such as phosphoric acid, nitric acid, and acetic acid (PAN etchant solutions, phosphoric nitric acetic acid).

(D) Subsequently, as illustrated in FIG. 6C, a portion of the passivation film 35 that is not covered by the first photoresist film 71 and the first transparent electrode film 36 is selectively removed by dry etching under conditions where the passivation film 35 is the removal target. Thus, as illustrated in FIG. 6D, the contact hole 50 extending to the TFT 60 through the first transparent electrode film 36 and the passivation film 35 is formed (contact hole formation process). Then, the first photoresist film 71 is removed by asking. Although not illustrated in FIG. 6D, the contact hole 50 in the first embodiment allows the semiconductor film 33, which constitutes the channel 64 of the TFT 60, to be exposed at a position away from a portion connected to the source electrode 62 (FIG. 5). Furthermore, in the first embodiment in which the passivation film 35 is a multi-layer film including a silicon nitride layer and a silicon oxide layer, the contact hole 50 is able to be formed by dry etching using etching gas that is a mixture of fluorine-containing gas, such as CF₄ and SF₆, and O₂or Ar. As illustrated in FIGS. 6C and 6D, since the photoresist formed of novolac resin is etched using the above-described etching gas, the pattern of the first photoresist film 71 deforms as the etching progresses. Thus, the opening 71H is widened and the diameter of the opening 71H is increased. Meanwhile, under the same etching conditions, the first transparent electrode film 36 formed of the IZO film is not practically etched at all, and thus the diameter of the opening 36H is unchanged. Thus, the passivation film 35 has the contact hole 50 having the diameter substantially the same as the diameter of the opening 36H formed in the first transparent electrode film 36 by the former etching or the original diameter of the opening in the first photoresist film 71.

(E) Next, as illustrated in FIG. 7A, a metal, such as Mo and MoW, or an alloy is sputtered on the upper surface of the first transparent electrode film 36 having the contact holes 50 to form the contact metal film 37 having light-blocking properties (contact metal film formation process). This contact metal film 37 covers the entire inner surface of the contact hole 50 and electrically connects the first transparent electrode film 36 with the TFT 60 (the semiconductor film 33 in the first embodiment) exposed to the inside of the contact hole 50. In the first embodiment, the contact metal film 37 is a Mo film formed of molybdenum as described above. Even when the IZO film is used as the first transparent electrode film 36 as described above, the metal forming the contact metal film 37 is not limited to molybdenum. As long as the contact metal film 37 is formed of a metal that is soluble in PAN etchant solutionins and ozone water and is capable of forming a light-blocking film, the electrode formation process and contact formation process are able to be performed.

(F-1) Next, a photoresist is applied onto the contact metal film 37 and developed after exposure to light using a photomask. Thus, as illustrated in FIG. 7B, the second photoresist film 72 having a pattern of the pixel electrode 55 is obtained. Examples of the photoresist include TFR series available from TOKYO OHKA KOGYO CO., LTD. as in the above-described process (B).

(F-2) Next, portions of the first transparent electrode film 36 and portions of the contact metal film 37 that are not covered by the second photoresist film 72 are selectively removed at the same time by dry etching or wet etching under conditions where the first transparent electrode film 36 and the contact metal film 37 are the removal targets such that the multi-layer film including the contact metal film 37 and the first transparent electrode film 36 is shaped into the shape of the pixel electrode 55 as illustrated in FIG. 7C (electrode formation process). Then, the second photoresist film 72 is removed by asking. In the first embodiment in which the first transparent electrode film 36 (IZO film) and the contact metal film 37 (Mo film) are the first transparent electrode film 36 and the contact metal film 37, unnecessary portions of the films 36 and 37 are removed at the same time by wet etching using a PAN etchant solution, such as phosphoric nitric acetic acid. When an element substrate is used for a reflection-type liquid crystal panel, the first transparent electrode film 36 and the contact metal film 37 may be left without etching to form the pixel electrode 55. In the element substrate 30 of the first embodiment for a transmission-type liquid crystal panel 10, the light-blocking contact metal film 37 (Mo film) on the pixel electrode 55 needs to be removed such that light can pass through the pixel electrode 55. This requires the following processes.

(G-1) Next, a photoresist is applied again onto the contact metal film 37, which has been shaped into the shape of the pixel electrode 55, and developed after exposure to light using a photomask. Thus, as illustrated in FIG. 7D, a third photoresist film 73 that has a pattern of a formation area of the contact hole 50 and a connection area between the opening edge of the contact hole 50 and the first transparent electrode film 36 is formed. Examples of the photoresist include TFR series (registered trademark) available from TOKYO OHKA KOGYO CO., LTD. as in the above-described processes (B) and (F-1).

(G-2) Next, portions of the contact metal film 37 that are not covered by the third photoresist film 73 are selectively removed by dry etching or wet etching under conditions where only the contact metal film 37 is the removal target (contact formation process). Then, the third photoresist film 73 is removed by asking. Thus, as illustrated in FIG. 7E, the transparent pixel electrode 55 formed of the first transparent electrode film 36 is formed, and the contact 56 connecting the pixel electrode 55 with the TFT 60 is formed. In the first embodiment in which the IZO film and the MO film are the first transparent electrode film 36 and the contact metal film 37, only unnecessary portions of the Mo film are selectively removed by wet etching using ozone water. Thus, at least a portion of the pixel electrode 55 is formed only of the first transparent electrode film 36, allowing the pixel electrode 55 to be a transparent electrode through which light passes. Meanwhile, the light-blocking contact 56 remains covering the inner surface of the contact hole 50 and the portion around the contact hole 50, and thus the light emitted from the backlight device to the contact 56 through the glass substrate GS is blocked at the contact hole 50 and the portion around the contact hole 50.

### Validation Experiment

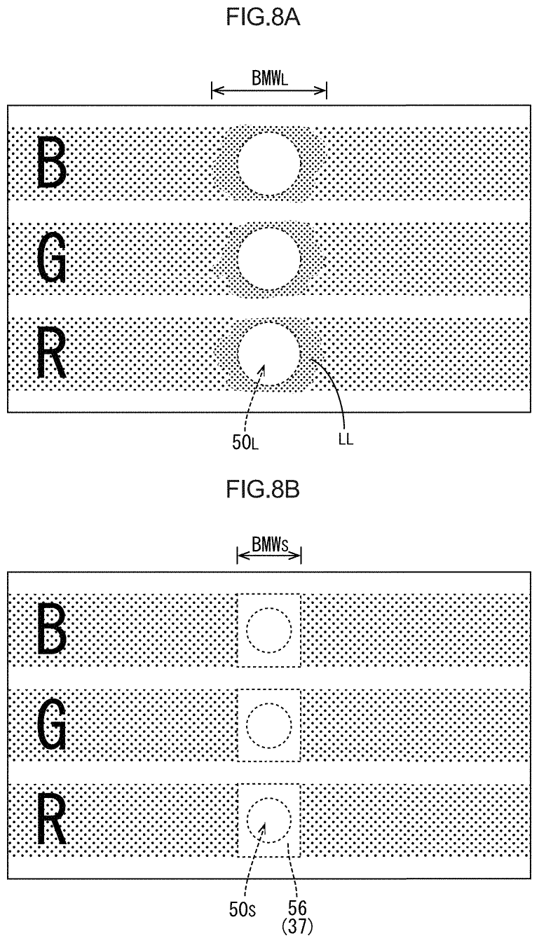

To validate the element substrate 30 produced by the above-described processes in respect of operations and effects, a liquid crystal panel for validation including a CF substrate having a color filter and not having a black matrix BM directly above the TFTs 60 was produced, and the light-emitting state thereof was observed. FIG. 8A schematically illustrates a light-emitting state of a comparative liquid crystal panel for validation that includes an element substrate produced by a conventional method. FIG. 8B schematically illustrates a light-emitting state of the liquid crystal panel for validation that includes the element substrate 30 produced by the above-described method.

In the conventional method, the contact hole 50_{L} is formed by using only the resist pattern formed of a photoresist as an etching mask. Thus, a reduction in diameter of the contact hole 50_{L} has a limitation, and as illustrated in FIG. 8A, the contact hole 50_{L} inevitably has a relatively large diameter. The three-dimensional structure including the contact hole 50_{L} and the step around the contact hole 50_{L} scatters or reflects the light passing through this area and disturbs the alignment of the liquid crystal material in the area including the contact hole 50_{L}, making the state of light transmitting through this area unstable and leading to light leakage LL over a relatively large area around the contact hole 50_{L}. The area where the light is likely to leak may be shielded from light to reduce a decrease in contrast caused by the light leakage. This requires a black matrix BM having a relatively large width BMW_{L} illustrated in FIG. 8A to cover a relatively large area of the CF substrate 20. This inevitably decreases the aperture ratio of the display screen, reducing the light transmittance of the liquid crystal panel.

In contrast, the production method in the first embodiment forms the contact hole 50s having a relatively small diameter as illustrated in FIG. 8B. Furthermore, since the contact 56 formed of the light-blocking contact metal film 37 is disposed in and around the contact hole 50s, the light does not pass through this area, and thus the light leakage due to scattering, reflection, and disturbed alignment is unlikely to occur. Thus, a high contrast is achieved simply by providing the black matrix BM having a relatively small width BMWs indicated in FIG. 8B over a relatively small area of the CF substrate 20. In some cases, the black matrix BM located directly above the TFTs 60 may be eliminated as in the liquid crystal panel for validation. The validation experiment revealed that the aperture ratio of the pixel PX was improved and the high transmission was achieved with the contrast being kept high.

As described above, the method of producing the element substrate 30 according to the first embodiment is a method of producing the element substrate 30 including the semiconductor film (conductive film) 33 constituting the TFT 60, the passivation film (insulating film) 35 located above the semiconductor film 33, and the pixel electrode (electrode) 55 located above the passivation film 35 and including the first transparent electrode film (transparent electrode film) 36 electrically connected to the semiconductor film 33. The method includes (A) the first transparent electrode film formation process of forming the first transparent electrode film 36 containing IZO (transparent metal oxide) on an upper side of the passivation film 35, (B) the first photoresist formation process of forming the first photoresist film (photoresist film) 71 on an upper side of the first transparent electrode film 36 and patterning the first photoresist film 71, (C) the first transparent electrode film opening formation process of selectively removing a portion of the first transparent electrode film 36 not covered by the patterned first photoresist film 71 to form the opening 36H extending through the first transparent electrode film 36, and (D) the contact hole formation process of selectively removing, by etching, a portion of the passivation film 35 not covered by the patterned first photoresist film 71 and the first transparent electrode film 36 having the opening 36H to form the contact hole 50 extending to the semiconductor film 33 through the first transparent electrode film 36 and the passivation film 35.

The inventors conducted a comprehensive study and found that the first transparent electrode film 36 formed of a transparent metal oxide, such as IZO and ITO, has higher etching selectivity and is less etched than a photoresist under conditions normally employed for dry etching of the passivation film 35. In the above-described configuration of the first embodiment, the first transparent electrode film 36 patterned to have the opening 36H is located above the passivation film and functions as an etching mask during etching of the passivation film 35. This configuration keeps the portion of the passivation film 35 around the opening to be covered by the first transparent electrode film 36 even if the opening in the first photoresist film 71 is widened as the etching progresses, preventing the portion of the passivation film 35 around the opening from being etched too much. Thus, the contact hole 50 having substantially the same diameter as the original opening in the pattern of the first photoresist film 71 formed by photolithography is formed in the passivation film 35. The contact hole 50 having a small diameter is reliably formed in the element substrate 30 with high accuracy. The liquid crystal panel (display panel) 10 including the element substrate 30 having the reduced diameter is less likely to have alignment defects caused, for example, by the contact hole 50 and the step around the contact hole 50, and thus liquid crystal panel 10 is able to have a smaller light-blocking area and a higher aperture ratio. Thus, a high-transmissive, high-contrast, and high-resolution liquid crystal panel 10 is obtained. In the element substrate 30 immediately after the contact hole formation process, components formed of the first transparent electrode film 36 are generally not formed. Thus, for example, after the contact hole formation process, if the first transparent electrode film 36 is removed by wet etching, which does not generate much etching residue, the substrate structure including the elements such as the TFTs 60 is not damaged. Furthermore, the transparent electrode film forming the pixel electrode 55 and the first transparent electrode film 36 used as the etching mask may be formed of the same material to simplify the material procurement and management.

Furthermore, in the method of producing the element substrate 30 of the first embodiment, the pixel electrode 55 is formed of the first transparent electrode film 36 located above the passivation film 35 and formed in a predetermined pattern. The method further includes (E) the contact metal film formation process of forming the contact metal film 37 having light-blocking properties on the upper surface of the first transparent electrode film 36 having the contact hole 50 to cover the entire inner surface of the contact hole 50 and to electrically connect a portion of the first transparent electrode film 36 around the opening with a portion of the semiconductor film 33 exposed to the inside of the contact hole 50, and (F) the electrode formation process of removing a portion of the contact metal film 37 and a portion of the first transparent electrode film 36 to shape the contact metal film 37 and the first transparent electrode film 36 into the shape of the pixel electrode 55.

In the above-described configuration of the first embodiment, the first transparent electrode film 36 used as an etching mask during the formation of the contact hole 50 is used as the pixel electrode 55 as it is. This simplifies the production process and is advantageous in respect of the material design and the material procurement and management, leading to a reduction in the production cost. Furthermore, in this configuration, the contact 56, which electrically connects the first transparent electrode film 36 forming the pixel electrodes 55 with the semiconductor film 33 of the TFT 60, is formed of the light-blocking contact metal film 37 and covers the inner surface of the contact hole 50 and the portion around the contact hole 50. Thus, the contact hole 50 possibly causing light leakage is shielded from light, effectively reducing display defects in and around the contact hole 50. Thus, a light-blocking layer including a metal film or a black matrix (BM) film and covering the contact hole 50 and the portion around the contact hole 50 to improve the contrast is made smaller or may be eliminated in some cases, enabling a high-transmissive pixel design.

Furthermore, in the method of producing the element substrate 30 of the first embodiment, the contact metal film 37 and the first transparent electrode film 36 are removed at the same time by wet etching in the electrode formation process.

In the configuration of the first embodiment, the first transparent electrode film 36 and the contact metal film are etched into the electrode pattern after the contact metal film 37 covers the inner surface of the contact hole 50. Thus, the substrate structure including the elements, such as the TFT 60, are unlikely to be damaged by etching. In the above-described configuration, the Mo film, which can undergo wet etching at the same time as the IZO film (first transparent electrode film 36), is employed as the contact metal film 37 and the electrode pattern is formed by wet etching. This reduces the production time, reducing defects caused, for example, by etching residue.

Furthermore, the method of producing the element substrate 30 of the first embodiment further includes (G) the contact formation process of removing all the contact metal film 37 having the shape of the pixel electrode 55 except a portion forming the inner surface of the contact hole 50 and a portion connected to the first transparent electrode film 36.

The above-described configuration of the first embodiment in which the unnecessary portions of the contact metal film 37 are removed in the contact formation process allows the pixel electrode 55 to have at least a portion including only the first transparent electrode film 36 and not including the contact metal film 37. The pixel electrode 55 becomes the transparent electrode through which light passes. Thus, the element substrate 30 including the transparent pixel electrodes 55 and to be included in a light-transmission-type liquid crystal panel 10 or organic EL panel is obtained. The contact metal film 37 is preferably removed by wet etching as described in the first embodiment to reduce the production time and etching residue.

Furthermore, the first embodiment discloses a method of producing the liquid crystal panel 10. The method includes the above-described process of producing the element substrate 30.

The above-described configuration of the first embodiment provides the super-high-resolution liquid crystal panel 10 that includes the element substrate 30 having the small-diameter contact hole 50 formed with high accuracy and has a high aperture ratio and less light leakage at a portion around the contact hole 50.

Furthermore, the element substrate 30 of the first embodiment includes, the semiconductor film 33 constituting the TFT 60, the passivation film 35 located above the semiconductor film 33, and the pixel electrode 55 located above the passivation film 35 and including the first transparent electrode film 36 electrically connected to the semiconductor film 33. The passivation film 35 has the contact hole 50 extending to the semiconductor film 33 through the passivation film 35. The contact metal film 37 having light-blocking properties covers the entire inner area of the contact hole 50 and electrically connects the first transparent electrode film 36 with a portion of the semiconductor film 33 exposed to the inside of the contact hole 50.

In the above-described configuration of the first embodiment in which the pixel electrode 55 is connected to the semiconductor film 33 of the TFT 60 by the light-blocking contact metal film 37, the contact hole possibly causing light leakage is shielded from light, effectively reducing display defects at the portion around the contact hole 50. Thus, the liquid crystal panel 10 including this element substrate 30 has a higher aperture ratio, resulting in high brightness and high contrast.

Furthermore, in the element substrate 30 of the first embodiment, the contact metal film 37 is not disposed over at least a portion of the pixel electrode 55, and the pixel electrode 55 is a transparent electrode through which light passes.

The light-transmission-type liquid crystal panel 10 having high brightness and high contrast is obtained by including the element substrate 30 of the first embodiment. Alternatively, when the element substrate 30 having the above-described configuration is employed in an organic EL panel, a bottom-emitting organic EL panel that transmits light toward an outer surface side (opposite the light-emitting layer) of the element substrate 30 is obtained.

Furthermore, the first embodiment discloses the liquid crystal panel 10 including the element substrate 30 having the above-described configuration.

The configuration of the first embodiment provides the liquid crystal panel 10 having the high aperture ratio, which results in high brightness and high contrast.

As described above, the configuration of the first embodiment enables the high-resolution liquid crystal panel 10 to be produced by a simple method.

### First Modification

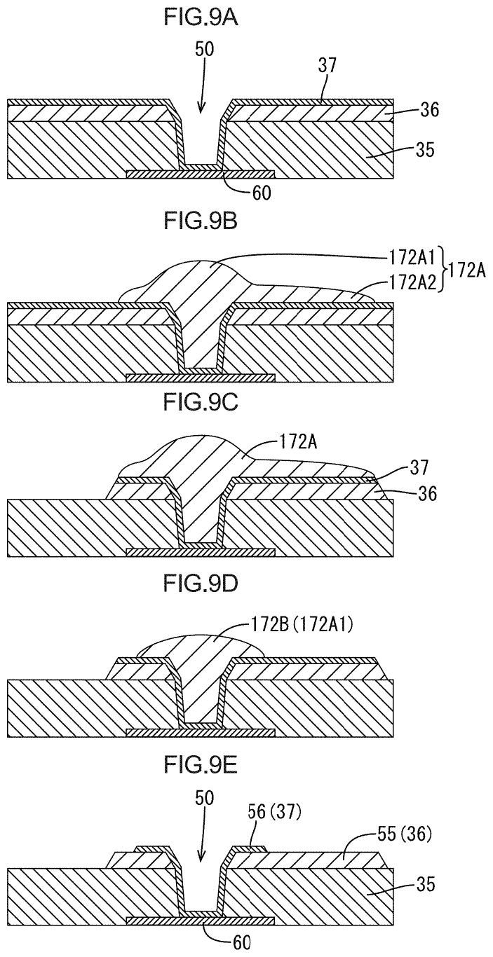

A first modification of the first embodiment is described with reference to FIGS. 9A to 9E. In the first modification, the liquid crystal panel 10 of the first embodiment is produced by a method slightly different from the method in the first embodiment. Specifically described, the method in the first modification differs from the method of producing an element substrate in the first embodiment in that the electrode formation process and the contact formation process are performed by using a second photoresist film 172A or 172B formed by using one half-tone mask or one gray-tone mask. In the first modification, components identical to those in the first embodiment are assigned the same reference numerals as those in the first embodiment and the operation and the effects thereof are not described (the same is applicable to the second embodiment and the following embodiments).

The first modification is characterized in that a half-tone mask or a gray-tone mask, which includes a semi-transmissive area that allows more light to pass than the other areas, is used as a photomask during the formation of the electrode. Specifically described, the processes of (F-1) to (G-2) in the first embodiment are changed to the following processes (F-101) to (G-102).

(F-101) A photoresist is applied onto the contact metal film 37 illustrated in FIG. 9A and developed after exposure to light using a half-tone mask or a gray-tone mask. As illustrated in FIG. 9B, this forms the second photoresist film 172A including a thick first resist portion 172A1 over a formation area of the contact 56 and a thin second resist portion 172A2 over a formation area of the pixel electrode 55.

(F-102) Next, a portion of the first transparent electrode film 36 and a portion of the contact metal film 37 that are not covered by the second photoresist film 172A (including the first resist portion 172A1 and the second resist portion 172A2) are selectively removed at the same time by dry etching or wet etching under conditions where the first transparent electrode film 36 and the contact metal film 37 are the removal targets. Thus, as illustrated in FIG. 9C, the multi-layer film including the contact metal film 37 and the first transparent electrode film 36 is shaped into the shape of the pixel electrode 55 (electrode formation process). In the first modification, the ashing for removing the entire second photoresist film 172A is not performed at this stage.

(G-101) Then, the thin second resist portion 172A2 of the second photoresist film 172A is selectively removed, and thus a second photoresist film 172B formed only of the first resist film 172A1 is obtained as illustrated in FIG. 9D. For example, the duration of the ashing is adjusted to selectively remove the second resist portion 172A2.

(G-102) Next, the portion of the contact metal film that is not covered by second photoresist film 172B is selectively removed by dry etching or wet etching under conditions where only the contact metal film 37 is the removal target (contact formation process). Then, the remaining second photoresist film 172B is all removed by asking. This forms the transparent pixel electrode 55 formed of the first transparent electrode film 36 and the contact 56 connecting the pixel electrode 55 with the TFT 60, as illustrated in FIG. 9E.

As described above, according to the method of producing the element substrate 30 of the first modification, the element substrate 30 having the same configuration as that in the first embodiment is obtained by the further simplified process using the reduced number of photomasks, which are relatively expensive.

### Second Embodiment

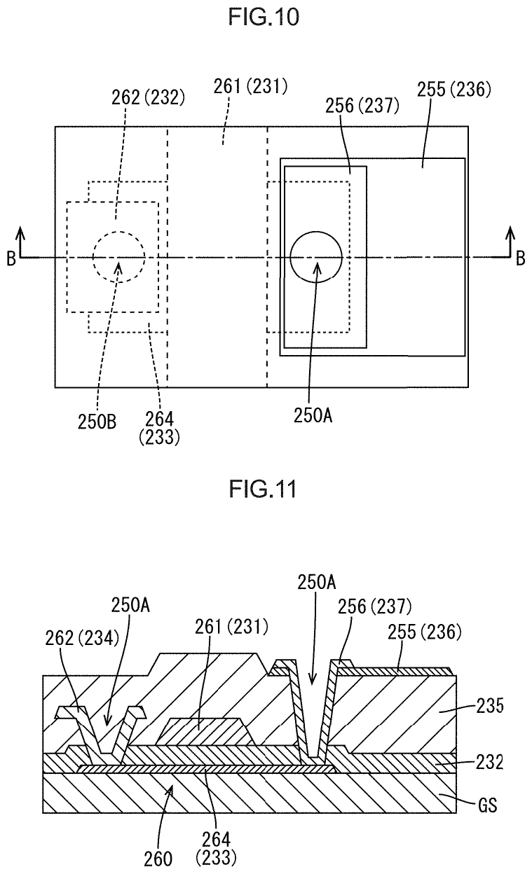

A second embodiment is described with reference to FIGS. 10 and 11. In the second embodiment, the present technology is applied to an element substrate 230 having a staggered TFT 260.

FIGS. 10 and 11 are views schematically illustrating a portion around connection between the TFT 260 and the pixel electrode 255 in the element substrate 230 according to the second embodiment. In FIG. 10, the gate insulating film 232 and the passivation film 235 are not illustrated as in FIG. 4 and the shapes of the electrodes of the TFT 260 and the pixel electrode 255 are simplified. In FIG. 11, the alignment film 30B is not illustrated as in FIG. 5. FIGS. 10 and 11 indicate the layout of the components and the shapes. The dimensions and the shapes of the components in FIGS. 10 and 11 are irrelevant to those of the components in FIGS. 4 and 5.

The inner layers of the element substrate 230 include, in this order from the lower side (adjacent to the glass substrate GS), a semiconductor film 233, a gate insulating film 232, a first metal film (gate metal film) 231, a second metal film (source metal film) 234, a passivation film (protective insulating film, one example of the insulating film) 235, a first transparent electrode film 236, a contact metal film 237, an interlayer insulating film, a second transparent electrode film, and an alignment film. The films have predetermined patterns (the contact metal film 237 and the underlying films are illustrated in FIG. 11). As illustrated in FIGS. 10 and 11, the multi-layer film forms the staggered (coplanar) TFT 260 in which the semiconductor film 233 forming a channel 264 is the lowest layer, the first metal film 231 forming a gate electrode 261 is disposed above the semiconductor film 233 with the gate insulating film 232 therebetween, and the second metal film 234 forming a source electrode 262 and the semiconductor film 233 are connected at a second contact hole 250B in the gate insulating film 232.

The TFT 260 is connected to the pixel electrode 255, which is formed of the first transparent electrode film 236, through the contact 256, which is formed of the contact metal film 237, in a contact hole 250A located at the portion of the semiconductor film 233 away from the portion connected to the second metal film 234. To produce the element substrate 230, the staggered TFTs 260 are formed on a glass substrate GS by a known method and then the passivation film 235 is formed in a solid pattern on the upper side of the TFTs 260 (the passivation film 235 may be formed of the same material as the passivation film 35 of the first embodiment). After this process, the processes (A) to (G-2) of the first embodiment may be performed to form the contact hole 250A, the transmissive pixel electrode 255, and the light-blocking contact 256 illustrated in FIGS. 10 and 11.

As described above, the method of producing the element substrate 230 of the second embodiment also stably forms the small-diameter contact hole 250A with high accuracy in the element substrate 230 having the staggered TFTs 260, as the method of producing the element substrate 30 of the first embodiment.

### Third Embodiment

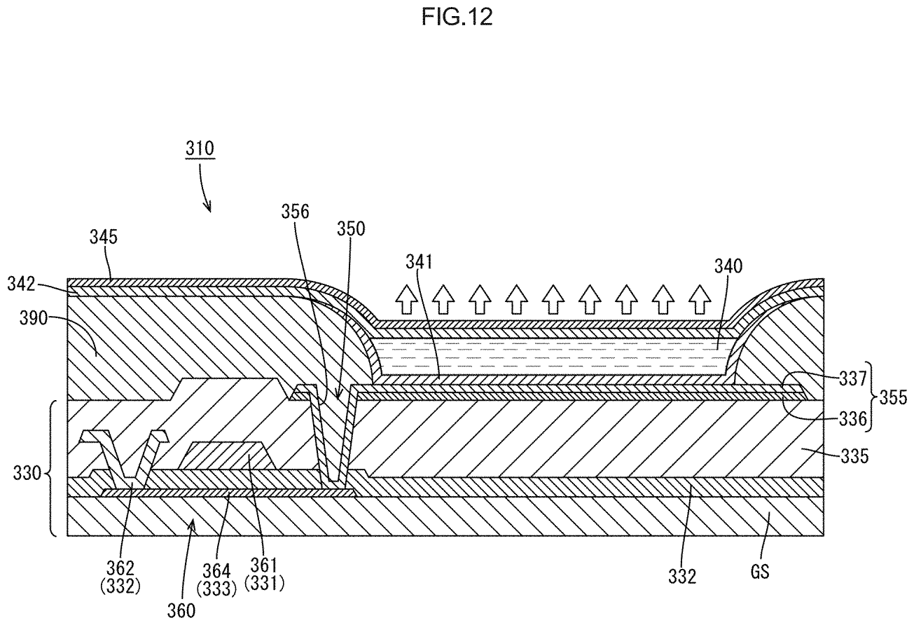

A third embodiment is described with reference to FIG. 12. In the third embodiment, the present technology is applied to a top-emitting organic EL panel (one example of a display panel) 310. The organic EL panel produced by using an organic EL material, which is a self-emitting electro-optical material, is viewable at a wide angle with high contrast and can be ultrathin compared with a liquid crystal panel. Thus, the organic EL panel is expected to be used in a display device of a mobile terminal or a wearable terminal, which are required to have super high resolution. The organic EL panels are classified into two types: a traditional bottom-emitting organic EL panel and a top-emitting organic EL panel according to the direction of the light. The bottom-emitting organic EL panel uses a light-transmitting transparent electrode as the pixel electrode to allow the light in the light-emitting layer to be output from the side of the element substrate. In contrast, the top-emitting organic EL panel does not need to have a light-transmitting pixel electrode and preferably uses a non-transparent reflective electrode that reflects light as the pixel electrode to allow the light in the light-emitting layer to be output from the side opposite the element substrate. The technology disclosed herein is applicable to both the bottom-emitting organic EL panel and the top-emitting organic EL panel. In the third embodiment, an element substrate 330 for a top-emitting organic EL panel 310 is described.

This technology is applicable to an organic EL panel having a known configuration. In the third embodiment, as illustrated in FIG. 12, the organic EL panel 310 includes an element substrate 330 including a pixel electrode 355 and other elements, a light-emitting layer 340 located above the element substrate 330 with a hole transport layer 341 therebetween and containing an organic EL element as a light-emitting element, and a common electrode 345 located above the light-emitting layer 340 with an electron transport layer 342 therebetween. The organic EL panel 310 of the third embodiment is a top-emitting organic EL panel in which light is output toward the upper side in FIG. 12 as indicated by arrows in FIG. 12. The pixel electrode 355 included in the element substrate 330 is a non-transparent reflective electrode, and the common electrode 345 is a transparent electrode formed of a transparent electrode material, such as ITO and IZO.

In the third embodiment, the element substrate 330 includes a staggered TFT 360 having the same configuration as the TFT 260 in the second embodiment. As illustrated in FIG. 12, the inner layers of the element substrate 330 of the third embodiment include, in this order from the lower side (adjacent to the glass substrate GS), a semiconductor film 333, a gate insulating film 332, a first metal film (gate metal film) 331, a second metal film (source metal film) 334, a passivation film (protective insulating film, one example of the insulating film) 335, a transparent electrode film 336, a contact metal film 337, and a resin film 390, which will be described later. These laminated films are formed in predetermined patterns. The laminated films form a staggered (coplanar) TFT 360 including a gate electrode 361, a source electrode 362, and a channel 364 in the same layout as those of the TFT 260 in the second embodiment.

The TFT 360 is connected to the pixel electrode 355 through the contact 356 formed of the contact metal film 337 at the contact hole 350. Here, the pixel electrode 355 in the third embodiment differs from the pixel electrode 55 in the first embodiment and the pixel electrode 255 in the second embodiment. The pixel electrode 355 is a non-transparent reflective electrode formed of a multi-layer film including the transparent electrode film 336 and the contact metal film 337 and reflects light. In the production of the element substrate 330 including the above-described pixel electrode 355, the staggered TFT 360 is formed on the glass substrate GS by a known method, and the passivation film 335 is formed in a solid pattern on the upper side of the TFT 360. After this process, for example, the processes (A) to (F-2) described in the first embodiment are performed, but the processes (G-1) and (G-2) are not performed. When the pixel electrode 355 is a reflective electrode as in the third embodiment, the contact metal film 337 is preferably formed of a high reflective metal, such as silver and aluminum. If the processes (G-1) and (G-2) are performed, a portion of the contact metal film 337 as the upper layer of the pixel electrode 355 is removed by etching and the transparent electrode film 336 as the lower layer remains unremoved, allowing a portion of the pixel PX to transmit light. Thus, an element substrate that constitutes a light-transmission-type organic EL panel is obtained.

The resin film 390 is formed of an insulating organic resin, such as PMMA and fills the contact hole 350 in the passivation film 335 to flatten the surface of the element substrate 330. In general, the multi-layer film of the organic EL panel is formed by repeated vapor deposition processes. If the substrate subjected to the vapor deposition has a rough surface, the surface would not be sufficiently masked, causing leakage between the pixels in some cases. Furthermore, the light-emitting state of the organic EL panel depends on the thickness of the light-emitting layer containing the organic EL material. Thus, the thickness of the light-emitting layer needs to be controlled to be substantially constant. Although the resin film 390 is disposed for the above-described purpose, the light-emitting layer 340 does not emit light if covered by the resin film 390. The area of the resin film 390 in the pixel region is required to be made as small as possible, i.e., the diameter of the contact hole 350 is required to be made as small as possible, to increase the light-emitting area for improvement in brightness.

As described above, in the element substrate 330 of the third embodiment, the contact metal film 337 is also disposed on the pixel electrode 355, and thus the pixel electrode 355 is a reflective electrode (light-blocking non-transparent electrode).

A reflective liquid crystal panel or a top-emitting organic EL panel 310 having high brightness and high contrast as the light-transmission-type liquid crystal panel 10 in the first embodiment is obtained by including the element substrate 330 having the configuration of the third embodiment.

Furthermore, the third embodiment discloses the organic EL panel 310 including the above-described element substrate 330.

According to the third embodiment, the organic EL panel 310 having a large light-emitting area and having high brightness and high contrast is obtained.

### Other Embodiments

The present technology is not limited to the embodiments described above and illustrated by the drawings. For example, the following embodiments will be included in the technical scope of the present technology.

(1) In the above-described embodiments, the IZO film containing IZO is used as the transparent electrode film, but the transparent electrode film is not limited to the IZO film. For example, an ITO film may be employed as the transparent electrode film instead of the IZO film. When the ITO film undergoes an annealing treatment, amorphous ITO undergoes crystallization and becomes poly-ITO, which is slightly soluble in PAN etchant solutions. This enables the contact formation process described in (G-2) or (G-102) to be performed by using a metal insoluble in ozone water. For example, in the electrode formation process in (F-2) of the first embodiment, an etchant solution that can dissolve ITO, such as an oxalic acid solution, is used to pattern the ITO film (transparent electrode film) and the contact metal film, and then, in the following contact formation process in (G-2), unnecessary portions of the contact metal film are dissolved by using the PAN etchant solution and removed from the ITO film crystallized by the annealing treatment. Thus, the transparent electrode including a pixel electrode having at least a portion formed only of the transparent ITO film (transparent electrode film) is obtained.

(2) In the above-described embodiments, the Mo film containing molybdenum is used as the contact metal film, but the present technology is not limited thereto. Any metal soluble in PAN etchant solutions and ozone water form transparent pixel electrodes by the method described in the first embodiment. Furthermore, a metal unnecessary for ozone water forms transparent electrodes as described in the above (1) if the metal is solvable in PAN etchant solutions and oxalic acid solutions. Alternatively, the contact metal film may be a multi-layer film including a titanium layer and an aluminum layer. After the resist patterning, the titanium layer is removed first by dry etching and then the aluminum layer is removed by wet etching using, for example, the PAN etchant solution. This forms the same structure. Materials and methods other than those described here may be employed as long as the contact metal film is selectively removal.

For example, as described in the third embodiment, the reflection-type pixel electrode does not require the contact formation process in which the unnecessary portion of the contact metal film is removed from the transparent electrode film.

(3) In the element substrate according to the present technology, the edge of the opening in the transparent electrode film may be located away from the edge of the opening in the passivation film, which is located below the transparent electrode film, toward the inner side or the outer side of the contact hole as long as the contact metal film is connected to the edge of the opening in the transparent electrode film without step-based disconnection. The term “step-based disconnection” here means disconnection caused at the edge of the contact hole by the contact metal film that does not sufficiently cover the step formed by the edge of the opening in the transparent electrode film or the passivation film.

(4) In the first embodiment, the contact 56 is connected to the semiconductor film 33 forming the channel 64 of the TFT 60 that does not have the drain electrode. However, the application of the present technology is not limited to the TFT 60 having such a configuration. The present technology is applicable to common TFTs including a drain electrode formed of the second metal film at a position on the semiconductor film opposite the source electrode, and a channel extending from the source electrode to the drain electrode to allow electrons to move between the electrodes. When the present technology is applied to the common TFTs, the contact hole is formed such that the drain electrode is exposed to the bottom. The drain electrode of the TFT and the pixel electrode are to be connected to each other through the contact metal film.

(5) In the above-described first embodiment, the liquid crystal panel 10 operates in the IPS mode, but the operation mode is not limited to the IPS mode. The image display mechanism and the operation mode of the liquid crystal panel are not limited. The present technology is applicable to liquid crystal panels operated in various modes, such as a vertical alignment (VA) mode and a twisted nematic (TN) mode. Furthermore, the application of the present technology is not limited to the element substrate included in the liquid crystal panel or the organic EL panel. The present technology is applicable to an element substrate included in another type of display panel, such a plasma display panel (PDP), an electrophoretic display panel (EPD), or a micro electromechanical system (MEMS) display panel.

(6) The present technology is applicable not only to an element substrate included in a display panel but also applicable to element substrates for various purposes.

1. A method of producing an element substrate including a conductive film, an insulating film located above the conductive film, and an electrode located above the insulating film and including a transparent electrode film electrically connected to the conductive film, the method comprising:
(A) a transparent electrode film formation process of forming the transparent electrode film containing a transparent metal oxide on an upper side of the insulating film;
(B) a photoresist formation process of forming a photoresist film on an upper side of the transparent electrode film and patterning the photoresist film;
(C) a transparent electrode film opening formation process of selectively removing a portion of the transparent electrode film not covered by the patterned photoresist film to form an opening extending through the transparent electrode film; and
(D) a contact hole formation process of selectively removing, by etching, a portion of the insulating film not covered by the patterned photoresist film and the transparent electrode film having the opening to form a contact hole extending to the conductive film through the transparent electrode film and the insulating film.

2. The method of producing an element substrate according to claim 1, wherein the electrode is formed of the transparent electrode film located above the insulating film and formed in a predetermined pattern, and
the method further comprising:
(E) a contact metal film formation process of forming a contact metal film having light-blocking properties on an upper surface of the transparent electrode film having the contact hole to cover the entire inner surface of the contact hole and to electrically connect a portion of the transparent electrode film around the opening with a portion of the conductive film exposed to the inside of the contact hole; and
(F) an electrode formation process of removing a portion of the contact metal film and a portion of the transparent electrode film to shape the contact metal film and the transparent electrode film into the shape of the electrode.

3. The method of producing an element substrate according to claim 2, wherein, in the electrode formation process, the portion of the contact metal film and the portion of the transparent electrode film are removed by wet etching.

4. The method of producing an element substrate according to claim 2, further comprising (G) a contact formation process of removing all the contact metal film having the shape of the electrode except a portion forming the inner surface of the contact hole and a portion connected to the transparent electrode film.

5. A method of producing a display panel comprising the process of producing an element substrate according to claim 1.

6. An element substrate comprising:
a conductive film;
an insulating film located above the conductive film; and
an electrode located above the insulating film and including a transparent electrode film electrically connected to the conductive film, wherein
the insulating film has a contact hole extending to the conductive film through the insulating film, and
a contact metal film having light-blocking properties covers the entire inner surface of the contact hole and electrically connects the transparent electrode film with a portion of the conductive film exposed to the inside of the contact hole.

7. The element substrate according to claim 6, wherein the contact metal film is not disposed over at least a portion of the electrode, and the electrode is a transparent electrode through which light passes.

8. The element substrate according to claim 6, wherein the contact metal film is disposed over the electrode, and the electrode is a non-transparent electrode having light-blocking properties.

9. A display panel comprising the element substrate according to claim 6.

10. The display panel according to claim 9, wherein the display panel is a liquid crystal panel.

11. The display panel according to claim 9, wherein the display panel is an organic EL panel.
